(19) United States
(12) Patent Application Publication
(10) Pub. No.: US 2004/0216670 A1
(43) Pub. Date: Nov. 4, 2004

(54) Process for the ALD coating of substrates and apparatus suitable for carrying out the process

(75) Inventors: Martin Gutsche, Dorfen (DE); Thomas Hecht, Dresden (DE); Gerhard Prechtl, Ramerberg (DE)

Correspondence Address: LERNER AND GREENBERG, PA, P O BOX 2480, HOLLYWOOD, FL, 33022-2480, US

(73) Assignee: Infineon Technologies AG

(21) Appl. No.: 10/836,147

(22) Filed: Apr. 30, 2004

(30) Foreign Application Priority Data
Apr. 30, 2003 (DE) 103 19 540.8

(51) Int. Cl. C23C 16/00

(52) U.S. Cl. 118/715; 427/248.1

(57) ABSTRACT

A process for ALD coating of substrates and an apparatus for carrying out the process includes providing a substrate in a reaction chamber, introducing a first precursor into the chamber to cause a pressure rise therein, starting from an initial pressure, to deposit a first layer constituent on the substrate surface, removing the first precursor from the chamber by purging with a purge gas such that the pressure in the chamber produced in the second step drops back to an initial pressure, introducing a second precursor into the chamber such that a pressure rise takes place in the chamber, starting from the initial pressure produced in the third step to deposit a second layer constituent on the substrate surface, and removing the second precursor from the chamber by purging with a purge gas such that the pressure in the chamber produced in the fourth step drops.

### BACKGROUND OF THE INVENTION

Field of the Invention

The present invention relates to a process for the ALD coating of substrates, and to an apparatus that is suitable for carrying out the process.

A known process for forming thin films is the chemical vapor deposition (CVD) process. In the CVD process, a chemical reaction takes place in the vapor phase, with the product of the chemical reaction being deposited as a solid on a substrate. The CVD process has long been known, in particular, as part of fabrication processes for semiconductor components, with insulating, semiconducting, and metallically conducting layers being applied. The CVD process is characterized by nucleation taking place on the substrate surface first. Then, these two-dimensional or three-dimensional nuclei grow together to form layers. CVD processes will often be unable to deposit layers of uniform thickness and sufficient homogeneity to meet future demands in the semiconductor industry. In particular, a non-uniform growth often occurs on account of islanding, etc.

A more recent process used to coat substrates, in particular semiconductor substrates, is the Atomic Layer Deposition (ALD) process. In the ALD process, precursors of different constituents of the film are brought into contact with the substrate surface alternately or in pulsed fashion. Each pulse of a precursor substance produces a chemical reaction on the surface of the substrate surface or wafer surface, producing an accurate thin film. Between pulses, the precursors are purged out of the reaction chamber using a purge gas. For example, if Al₂O₃ is to be deposited, a precursor for Al is applied first, followed by a pulse of a purge gas, and, then, a precursor for “O” is applied so that a defined layer of Al₂O₃ is formed on the substrate surface.

ALD reactors are available both as single wafer ALD reactors, which are configured for the ALD coating of a single substrate or wafer, and as batch ALD reactors, in which a plurality of substrates or wafers can be coated simultaneously.

To produce a layer that is, as far as possible, homogeneous, uniformly thin, and free of impurities, a CVD mechanism should be avoided as far as possible. Therefore, in the ALD process it is ensured that the precursors that are responsible for the deposition are, as far as possible, not simultaneously present in the reaction chamber, in order to avoid CVD deposition at the surface and/or particle formation in the vapor phase. Currently, this is achieved by alternating introductions of precursor and purge gas; for thicker layers, a plurality of cycles can be carried out in succession. For example, if Al₂O₃ is to be deposited, a typical, conventional, four-stage deposition cycle using the precursors trimethylaluminum (TMA) for aluminum and H₂O for oxygen, in a single wafer ALD reactor, by way of example, involves the following:

a) 200 ms TMA deposition;

b) 2000 ms N₂ purge;

c) 400 ms H₂O deposition; and

d) 2000 ms N₂ purge.

Accordingly, thicker Al₂O₃ layers can be produced by repeating these cycles.

In terms of the introduction of the precursors, ALD processes according to the prior art are carried out such that, when the precursor is being introduced to be brought into contact with the substrate surface, gas is simultaneously discharged, i.e., substantially a constant pressure is present in the reaction chamber during introduction of the precursor into the reaction chamber. This procedure is based on the assumption that there is an equilibrium between precursor and reactant at the substrate surface so that, by discharging the reactant, it is possible to shift the reaction equilibrium toward the products and/or to avoid a reverse reaction. This has the drawback that when the reactants are being discharged, undeposited precursors are also simultaneously removed from the reaction chamber. This firstly lengthens the time required for the deposition process and secondly means that a proportion of the precursor is lost to the process without being utilized.

In conventional ALD processes, the purging that follows the precursor being supplied, moreover, takes place either only after the precursor has been pumped out (without purge gas), or the purging and pumping out of the precursor take place at a constant chamber pressure. In technical terms, these procedures are considered the simplest to realize.

A drawback of these processes is that the precursor concentration in the reaction chamber decreases only slowly as a result of the processes according to the prior art, with the result that the cycle times and, therefore, the overall production times, are lengthened.

### SUMMARY OF THE INVENTION

It is accordingly an object of the invention to provide a process for the ALD coating of substrates and an apparatus suitable for carrying out the process that overcome the hereinafore-mentioned disadvantages of the heretofore-known devices and methods of this general type and that allow the duration of the ALD process to be shortened and, moreover, allow a greater proportion of precursor to be used for coating, reduce the consumption of precursor, and carry out the ALD process as a whole within a shorter time.

With the foregoing and other objects in view, there is provided, in accordance with the invention, a process for the ALD coating of substrates, includes the steps of:

a. providing a substrate in a reaction chamber;

b. introducing a first precursor into the reaction chamber, such that a pressure rise occurs in the reaction chamber, starting from an initial pressure, to achieve deposition of a first layer constituent on the substrate surface;

c. removing the first precursor from the reaction chamber by purging with a purge gas such that the pressure in the reaction chamber that was produced in step b. drops back to an initial pressure;

d. introducing a second precursor into the reaction chamber such that a pressure rise takes place in the reaction chamber, starting from the initial pressure produced in step c., to achieve deposition of a second layer constituent on the substrate surface; and

e. removing the second precursor from the reaction chamber by purging with a purge gas such that the pressure in the reaction chamber produced in step d. drops.

With the objects of the invention in view, there is also provided a method for ALD coating of substrates, including the steps of providing a substrate in a reaction chamber, starting from an initial pressure, raising the pressure in the reaction chamber by introducing a first precursor therein to effect deposition of a first layer constituent on a surface of the substrate, purging the reaction chamber with a purge gas to remove the first precursor from the reaction chamber and to reduce the pressure in the reaction chamber substantially back to the initial pressure, starting from the initial pressure, raising the pressure in the reaction chamber by introducing a second precursor therein to effect deposition of a second layer constituent on the substrate surface, and purging the reaction chamber with a purge gas to remove the second precursor from the reaction chamber and to drop the pressure in the reaction chamber from the raised pressure caused by introduction of the second precursor.

A crucial factor of the process according to the invention is that the precursors are introduced such that a pressure rise occurs in the reaction chamber. This is, preferably, achieved by virtue of introducing the precursor gas more quickly than gas is discharged from the reaction chamber.

In the text that follows, the present invention is explained, by way of example, substantially based upon two precursors so that binary layers are formed. However, it will be understood that the present invention is also suitable for the deposition of multi-component layer systems, in particular, for the ALD deposition of ternary or quaternary layers. In such cases, steps b. to d. are followed by further steps using further precursors. For example, in a ternary layer system, step e. is followed by a further step f. of introducing a third precursor into the reaction chamber such that a pressure rise takes place in the reaction chamber, starting from the initial pressure produced in step e., in order for a third layer constituent to be deposited on the substrate surface. This is followed by a step g. of removing the third precursor from the reaction chamber by purging with a purge gas such that the pressure in the reaction chamber produced in step f. drops. Then, it is, once again, possible for the first precursor to be deposited in accordance with step b. In a quaternary system, accordingly, a fourth precursor would be introduced, followed by subsequent purging. In a preferred embodiment of the present invention, a ternary or four-component layer system is deposited in accordance with the invention. Of course, the explanations and statements given below in connection with steps b. to e. also apply to any subsequent steps for introducing and purging further precursors.

In accordance with another mode of the invention, when the respective precursor is being introduced, the reaction chamber is closed apart from the feedline for the precursor, i.e., in this process step, no gas is being discharged from the reaction chamber. Because there is no gas being pumped out, or at least this operation is greatly restricted, less unused precursor escapes through the off-gas lines. Surprisingly, the procedure according to the invention makes it possible to shorten the cycle time without having an adverse effect on the quality of the layers that are deposited. This is assumed to be based on the fact that, on one hand, there is sufficient precursor and this precursor is optimally used for deposition, although it could also be assumed that reaction products that are not discharged interfere with the layer formation. This assumption also forms the basis for the procedure according to the prior art, i.e., introduction of the precursor into the reaction chamber at a substantially constant pressure.

Surprisingly, according to the invention it was possible to obtain excellent homogeneous thin films of very good quality, even though the constituents not required for deposition are not removed from the reaction chamber.

In accordance with a further mode of the invention, the pressure rise in step b. and/or d. takes place such that the pressure in the reaction chamber is increased by a factor of approximately 2 to approximately 6, preferably, approximately 2 to approximately 4, after the respective precursor has been introduced. However, the invention, likewise, also encompasses pressure rises by factors from approximately 1.5 to over 6, for example, 10 or above.

The initial pressures and pressure rises in steps b. and d., and, in the case of multi-component layer systems, also the further steps, of the process according to the invention are fundamentally independent of one another, i.e., by way of example, it is possible to select a different initial pressure for the first precursor than for the second precursor. In a preferred embodiment, the initial pressures for the first and second precursors are approximately equal. According to the invention, it is also possible for the pressure rises for the first and second precursors to be different. In a preferred embodiment, the pressure rises while the first and second precursors are being introduced are substantially equal.

The pressure rise can be varied, first, by the pressure at which the precursor is introduced and, second, by the period of time for which the precursor is introduced. In the case of closed discharge lines, the pressure rises as the time increases.

The initial pressures and pressure rises may also be dependent on the ALD reactor used. Suitable initial pressure conditions can also be varied within a wide range by the person skilled in the art as a function of the ALD apparatus used, the precursor used, and the substrate. In a preferred embodiment of the invention, the initial pressures in step b. and d. are, independently of one another, approximately 50 to 500 mtorr, preferably, approximately 100 to 300 mtorr, for a single-wafer ALD reactor, and approximately 200 to 800 mtorr, preferably, also approximately 300 to 700 mtorr, for a batch ALD reactor.

The precursor introduction times can be shortened by a factor of approximately 2 under otherwise identical conditions and to form a layer of comparable thickness by using the process according to the invention.

In accordance with an added mode of the invention, the pressures after the introduction of the respective precursors has ended may, according to the invention, vary within a wide range and can be suitably adapted by the person skilled in the art. According to the invention, for example, pressures of up to 1 torr or even above are eminently suitable for a single-wafer ALD reactor. By way of example, pressures of up to 9 torr are eminently suitable for a batch reactor. In accordance with a preferred embodiment, the pressures that are built up in step b. and d., at the end of introduction of the precursor in question, are approximately 150 to 1500 mtorr, more preferably, 400 to 800 mtorr, more preferably, approximately 400 to 600 mtorr, for a single-wafer ALD reactor, and approximately 800 mtorr to 7 torr, preferably, approximately 1 to 5 torr, for a batch ALD reactor.

According to the invention, suitable process windows in terms of the pressures are, for example, pressure ranges in the reaction chamber from 50 mtorr to 1 torr for a single-wafer ALD reactor, and, for example, from 300 mtorr to 7 torr for a batch ALD reactor. Within these ranges, the person skilled in the art can determine a suitable range for the particular coating. In this context, it is preferable to maintain the abovementioned factors for the pressure rise.

An example of a preferred pressure range for the formation of an Al₂O₃ layer by ALD using the precursors TMA and H₂O in a single-wafer ALD reactor is:

TMA: initial pressure=200 mtorr, final pressure=400 mtorr

Purge: start=400 mtorr, end=100 mtorr; and

H₂O: initial pressure=100 mtorr, final pressure=300 mtorr

Purge: start=300 mtorr, end=200 mtorr.

And for a BATCH ALD reactor:

Initial pressure=200 mtorr, final pressure=1 torr

Purge: start=1 torr, end=200 mtorr.

In accordance with an additional mode of the invention, steps b. to d. according to the invention can be repeated until a desired layer thickness has been reached; if the cycle is repeated, the pressure after step e. has ended corresponds to the initial pressure for introduction of the first precursor.

According to steps c. and e. of the present invention, the first or second precursor are removed from the reaction chamber by purging such that the pressure that has previously been built up in the reaction chamber during introduction of the precursor in question drops back to an initial pressure so that a precursor can, once again, be introduced. Surprisingly, rapid removal of the precursor from the reaction chamber, by rapid purging under conditions that are such that a pressure drop occurs, does not disrupt the layer formation in the ALD process.

Such a pressure drop in the reaction chamber during purging can be achieved, according to the invention, by using a pump to discharge gas from the reaction chamber more quickly than purge gas is introduced into the reaction chamber.

In accordance with yet another mode of the invention, the purging with a pressure drop in the reaction chamber should be carried out such that, on one hand, at a predetermined pump power, for example, preferably at maximum pump power in the case of conventional installations, there is not too much and not too little purging. In the event of insufficient purging, the process approximately corresponds to a process that simply uses pumping, whereas, if the purging is excessive, the pump power drops. By way of example, in the case of a batch ALD reactor with a reactor volume of 0.074 m³ and a maximum pump power of 1000 l/min., a suitable purge value is approximately 5 slm. FIG. 4 gives the residual precursor concentration as a function of the purging flow. FIG. 2 shows the decrease in the precursor concentration (TMA as an example) over the course of time in the purging process according to the invention compared to the prior art.

The procedure that results in a pressure drop in the reaction chamber during purging allows the precursor to be removed from the reaction chamber significantly more quickly than in the case of purging at constant chamber pressure or in the case of evacuation of the reaction chamber without purge gas. The procedure according to the invention makes it possible to shorten the purge times by a factor of approximately 5 compared to processes according to the prior art.

The total cycle times can, overall, be considerably shortened, in accordance with the shortening of the introduction of precursor by a factor of approximately 2 and the shortening of the purging by a factor of approximately 5. At the same time, utilization of the precursor is improved so that the consumption of precursor can be significantly reduced.

Existing ALD processes and apparatuses currently have problems with regard to contamination of the reaction chamber and therefore also disruption to deposited layers. This is substantially based on the fact that CVD and, also, ALD reactions, with corresponding particle formation, can occur in the off-gas lines. As a result, the off-gas lines are constantly contaminated. In particular, the reaction products that result from diffusion can pass back into the reaction chamber in the procedures according to the prior art, which has a disruptive effect on the deposition.

In accordance with yet a further mode of the invention, therefore, the first precursor and the second precursor are removed from the reaction chamber through different off-gas lines. In addition, it is preferable for a dedicated pump to be used for each individual off-gas line. This, in particular, makes it possible to prevent the above-described disruptive deposition or particle formation in the off-gas lines because deposits and/or particles of this nature can only form in the gas lines if the two different precursors come into contact with one another. Accordingly, diffusion of particles that have been produced back into the reaction chamber also cannot occur. The temporally and spatially separate gas discharge according to this preferred embodiment of the invention means that these undesired situations in the off-gas lines, i.e., the two precursors simultaneously in the gas phase or at the surface, no longer occur. It is advantageous for each off-gas line for each precursor also to have a dedicated valve. These valves can be used to open and close the off-gas lines separately and/or to close them both. Alternatively, it is possible to use one valve for both off-gas lines, in which case the valve can alternately close between the off-gas lines or can also close both off-gas lines simultaneously.

In the case of a ternary or multi-component layer system, in accordance with yet an added mode of the invention, it is, likewise, possible to select different off-gas lines for all the precursors. In the case of multi-component layer systems in which precursors do not form disruptive deposits, however, this measure is to this extent not required. For example, in the ternary system Al,Hf oxide, it is possible to provide a common off-gas line for Al and Hf and their precursors.

In accordance with yet an additional mode of the invention, moreover, different feedlines are provided for the first and second precursors. In a further preferred embodiment, furthermore, at least one further feedline for the purge gas is provided.

The process according to the invention is suitable, in particular, for the ALD coating of semiconductor substrates, metallic substrates, or insulating substrates, or substrates with insulating layers and/or metallic layers, used in semiconductor fabrication.

Furthermore, the present invention relates to an apparatus for carrying out an ALD process, which includes the following components: a reaction chamber, at least one feedline for a first precursor, at least one further feedline for a second precursor, optionally, one or more further feedlines for one or more further precursors, at least one feedline for a purge gas, at least one off-gas line for the first precursor, at least one other off-gas line for the second precursor and, optionally, one or more further off-gas lines for one or more further precursors. An apparatus of this type is diagrammatically depicted in FIG. 1.

With the objects of the invention in view, there is also provided a device for carrying out a deposition process, including an Atomic Layer Deposition reaction chamber, at least one first feedline fluidically connected to the reaction chamber for supplying a first precursor to the reaction chamber, at least one second feedline fluidically connected to the reaction chamber for supplying a second precursor to the reaction chamber, at least one purge feedline fluidically connected to the reaction chamber for supplying a purge gas to the reaction chamber, at least one off-gas line fluidically connected to the reaction chamber, a first valve disposed in the at least one first off-gas line, the first valve venting at least some of the first precursor from the reaction chamber when in an open position, at least one second off-gas line fluidically connected to the reaction chamber, and a second valve disposed in the at least one second off-gas line, the second valve venting at least some of the second precursor from the reaction chamber when in an open position.

In accordance with again another feature of the invention, the off-gas line for the first precursor and the off-gas line for the second precursor are, advantageously, connected to different pumps.

In accordance with again a further mode of the invention, it is preferable for the apparatus to have valves at each off-gas line for the first and second precursors, in order to allow the off-gas lines to be closed off from the reaction chamber.

In accordance with a concomitant feature of the invention, if multi-component layers, such as, for example, ternary or quaternary layer systems, are being deposited, it is possible to provide further off-gas lines and feedlines, in particular, off-gas lines, in the apparatus according to the number of further precursors. However, this is not necessary if certain precursors do not react with one another to form disruptive particles. In such a case, a common off-gas line can be provided for these precursors that do not react with one another.

The process and the apparatus of the present invention can be used regardless of the precursor and purge gas used and, therefore, apply to all conceivable combinations of precursors and purge gases. Examples of such combinations include:

Dielectric Layers:

| Layer: | Precursors: |
|---|---|
| Al₂O₃ | TMA/H₂O |
| HfO₂ | HfCl₄/H₂O, Hf(NMe₂)₄/H₂O, Hf(NEtMe)₄/H₂O, |
| | Hf (NEt₂)₄/H₂O |
| ZrO₂ | ZrCl₄/H₂O |

It is, in each case, possible for O₃ to be used as precursor instead of H₂O.

Metallic Layers:

| Layer: | Precursors: |
|---|---|
| W₂N | WF₆/NH₃ |
| TiN | TiCl₄/NH₃ |

Examples of ternary layers are aluminum-hafnium-oxide or aluminum-zirconium-oxide layers. According to the invention, these represent preferred ternary systems. Examples of quaternary systems include aluminum-hafnium-zirconium-oxide layers. In such a case, it is in each case possible to use the abovementioned precursors for forming layers of ternary or quaternary systems.

According to the invention, the precursors are, generally, introduced into the reaction chamber in combination with a carrier gas, as is customary in ALD processes. Carrier gases used may be standard inert gases, such as N₂ or the like. According to the invention, the precursors are present in the carrier gases in standard concentrations, for example, preferably, approximately 10 to 50% by weight, in particular, approximately 20 to 35% by weight.

The purge gases used may be all conventional and appropriate inert purge gases, such as, for example, N₂, H₂, He, Ar, Ne, Kr, Xe, or combinations thereof. The flow rates at which the precursors are introduced can be determined by the person skilled in the art for a specific reactor volume. Flow rates for the deposition of precursors that are used in a single wafer ALD reactor are, according to the invention, in a range from approximately 100 sccm to 1 slm. For a batch ALD reactor, the flow rates may, for example, be in the range from approximately 1 slm to 10 slm.

According to the invention, the deposition temperatures can be matched to the substrate that is to be coated and the precursors used by the person skilled in the art. According to the invention, they are usually approximately 150 to 450° C., preferably, approximately 300° C., in particular for the precursors TMA and H₂O.

Other features that are considered as characteristic for the invention are set forth in the appended claims.

Although the invention is illustrated and described herein as embodied in a process for the ALD coating of substrates and an apparatus suitable for carrying out the process, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a block diagram of an ALD apparatus for carrying out the process according to the present invention;

FIG. 2 is a graph illustrating a decrease in a precursor concentration (TMA) over the course of time with different purging methods;

FIG. 3 is a graph illustrating a temporal curve of a TMA partial pressure under ALD process conditions in accordance with the prior art and for the process according to the invention; and

FIG. 4 is a graph illustrating the residual precursor concentration as a function of the purge flow.

### DESCRIPTION OF THE PREFERRED EMBODIMENTS

By way of example, the following text describes the deposition of an Al₂O₃ layer by ALD processes according to the invention using apparatuses according to the invention. However, the invention is not restricted to such a system. In particular, the present invention also encompasses the deposition of layers that are formed from a plurality of precursors, for example three or four precursors.

1. Single Wafer ALD Reactor

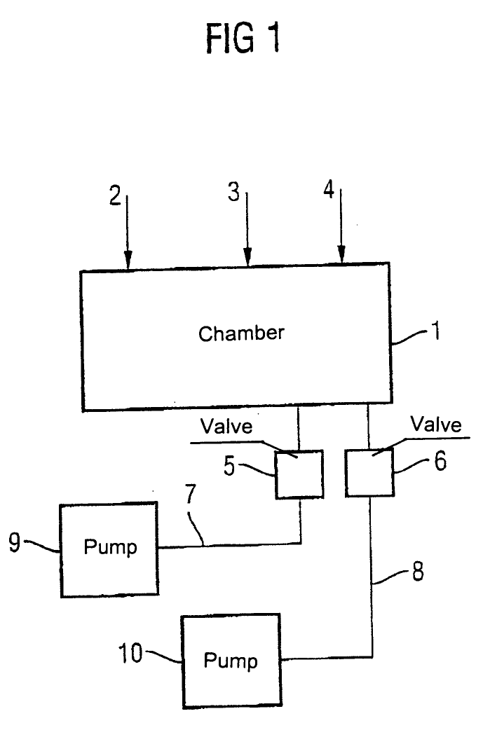

Referring now to the figures of the drawings in detail and first, particularly to FIG. 1 thereof, there is shown, first of all, in the first step of the deposition cycle, that a TMA deposition was performed on a substrate (Si wafer) in a reaction chamber 1. The reaction chamber had a volume of 2 l. TMA mixed with nitrogen, with a TMA content of approximately 30% by volume, introduced into the reaction chamber 1 through line 2 at a flow rate of 450 sccm. The deposition temperature was 300° C. The introduction was carried out for 200 ms. The pressure in the reaction chamber rose from an initial pressure of 200 mtorr to a pressure of 400 mtorr during these 200 ms.

The TMA was supplied in a typical single-wafer ALD reactor. During the TMA deposition, both valves 5, 6 in accordance with FIG. 1 were closed. Alternatively, if just one valve is provided for both off-gas lines, it is possible for such a valve to close off both off-gas lines.

FIG. 3 shows the temporal curve of the TMA partial pressure under process conditions in accordance with the prior art (dashed lines) and for the process according to the invention (solid lines). In FIG. 3, in accordance with the exemplary embodiment, TMA forms a proportion of approximately 30%, and is used in combination with nitrogen. Multiplying the partial pressure of TMA in FIG. 3 after 200 ms gives the reaction chamber pressure of approximately 400 mtorr (approximately 54 Pa). FIG. 3 shows that when TMA is introduced under a constant pressure for 200 ms in accordance with the prior art, the TMA partial pressure is significantly lower than with the procedure according to the invention. Furthermore, the precursor introduction time can be shortened by a factor of approximately 2 compared with the prior art.

This is followed by a second step, in which residual TMA and reaction products are purged out by feedline 4 by N₂ as purge gas. The N₂ purge was carried out for 400 ms. The prior art would have required a purge time of approximately 2000 ms. Valve 5 opened up off-gas line 7 so that TMA was removed from the reaction chamber by pump 9. The flow rate was 450 sccm, while the pump power was 1000 l/min. Accordingly, during the purging, a considerable pressure drop occurred in the reaction chamber 1, from 400 mtorr to approximately 100 mtorr.

This was followed by introduction of the second precursor H₂O, as a 30% strength mixture with N₂, through line 3 into the reaction chamber 1 for 200 ms. Both valves 5 and 6 were closed. H₂O was introduced at a temperature of 300° C. and a gas flow rate of approximately 450 sccm. The final pressure after 200 ms was 300 mtorr.

Finally, in a further step, the second precursor H₂O was purged out by line 4 by N₂ for approximately 300 or 400 ms. The purging conditions were as described above. The pressure after the end of purging was 200 mtorr. In such a case, valve 6 was opened, and H₂O and reaction products were removed through line 8 by pump 10.

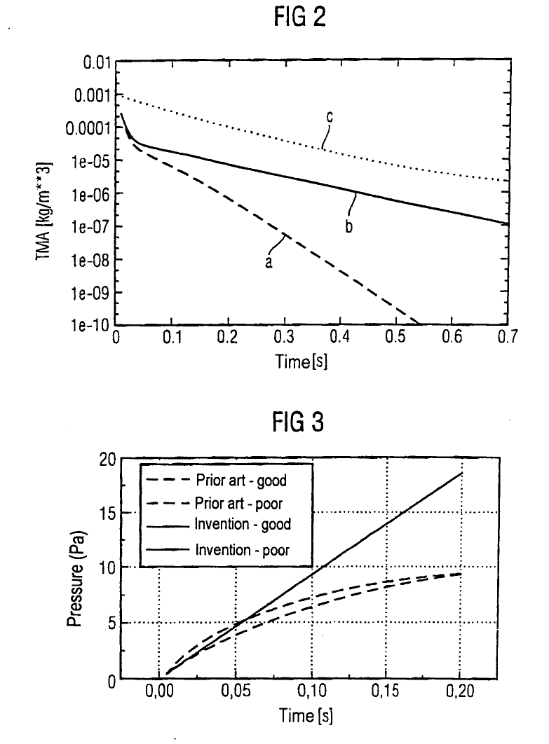

FIG. 2 shows a procedure according to the invention that can be achieved with simultaneous purging and pumping-out with a high pump power (a, according to the invention) compared to pumping-out and purging at constant pressure (b), and in the case of pumping-out without purge gas (c). By way of example, FIG. 2 shows curves for the removal of TMA from the reaction chamber in the exemplary embodiment that has just been described. It can be seen that with strong pumping-out, e.g., at maximum pump power, with simultaneous purging, a greatly shortened time is required to remove TMA from the reaction chamber. Despite the lack of constancy in the conditions inside the reaction chamber, this surprisingly, has no adverse effect on the quality of the deposition layers that are produced.

2. Batch ALD Reactor

As in Example 1, an Al₂O₃ coating was performed on Si wafers, but, in this case, in a batch ALD reactor with a reaction chamber volume of 0.074 m³.

The following cycle was performed:

a. First precursor TMA; 470 ms; 20% by volume of TMA in N₂; flow rate 5 slm; deposition temperature 300° C. Initial pressure 200 mtorr; final pressure 1 torr.

b. Purging with N₂; 700 ms; pump power 1000 l/min; pressure drop from 1 torr to 200 mtorr.

c. Second precursor H₂O; 470 ms; 20% by volume H₂O in N₂; flow rate 5 slm; deposition temperature 300° C. Initial pressure 200 mtorr; final pressure 1 torr.

d. Purging with N₂; 1000 ms; pump power 1000 l/min; pressure drop from 1 torr to 200 mtorr.

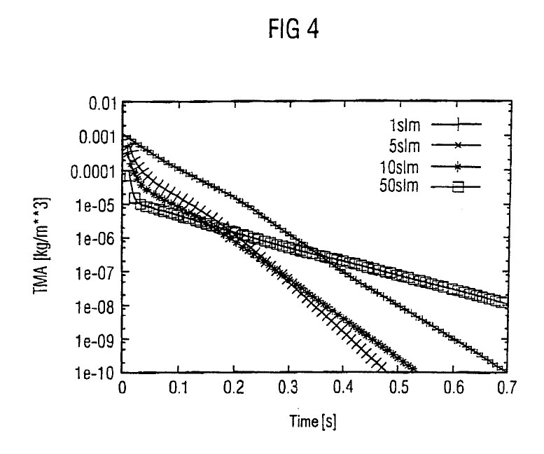

A suitable gas flow rate for the introduction of the purge gas had, in this example, previously been determined experimentally. FIG. 4 plots, for the batch ALD reactor with a volume of 0.074 m³ used, the decrease in the TMA concentration over the course of time for different gas flow rates. It can be seen that for a gas flow rate of 5 slm, the TMA concentration is sufficiently low after approximately 700 ms. Although gas flow rates of 10 or 50 slm can shorten this time, this initially results in relatively strong pressure drops, in particular, in the initial range. Moreover, the decrease in the TMA concentration is no longer greatly shortened in relation to the gas flow rate employed. Therefore, in this case, a value of 5 slm was selected.

In both examples, it was possible to significantly shorten the overall deposition times without having any adverse effect on the layer quality.

This application claims the priority, under 35 U.S.C. § 119, of German patent application No. 103 19 540.8, filed Apr. 30, 2003; the entire disclosure of the prior application is herewith incorporated by reference.

We claim:

1. A method for ALD coating of substrates, which comprises:
a. providing a substrate in a reaction chamber;
b. introducing a first precursor into the reaction chamber a manner that a pressure rise occurs in the reaction chamber starting from an initial pressure to achieve deposition of a first layer constituent on a surface of the substrate;
c. removing the first precursor from the reaction chamber by purging with a purge gas such that the pressure in the reaction chamber produced in step b. drops back to approximately the initial pressure;
d. introducing a second precursor into the reaction chamber such that a pressure rise takes place in the reaction chamber, starting from the initial pressure produced in step c., to achieve deposition of a second layer constituent on the substrate surface; and
e. removing the second precursor from the reaction chamber by purging with a purge gas such that the pressure in the reaction chamber produced in step d. drops.

2. The method according to claim 1, which further comprises achieving the raised pressure in the reaction chamber in at least one of step b. and step d. by placing the reaction chamber in a closed state during introduction of the respective one of the first and second precursors.

3. The method according to claim 1, which further comprises effecting the pressure rise in at least one of step b. and step d. by increasing the pressure in the reaction chamber by a factor of between approximately 2 and approximately 6 after introduction of the respective one of the first and second precursors has ended.

4. The method according to claim 2, which further comprises effecting the pressure rise in at least one of step b. and step d. by increasing the pressure in the reaction chamber by a factor of between approximately 2 and approximately 6 after introduction of the respective one of the first and second precursors has ended.

5. The method according to claim 1, which further comprises effecting the pressure rise in at least one of step b. and step d. by increasing the pressure in the reaction chamber by a factor of between approximately 2 and approximately 4 after introduction of the respective one of the first and second precursors has ended.

6. The method according to claim 2, which further comprises effecting the pressure rise in at least one of step b. and step d. by increasing the pressure in the reaction chamber by a factor of between approximately 2 and approximately 4 after introduction of the respective one of the first and second precursors has ended.

7. The method according to claim 1, which further comprises setting the initial pressures in steps b. and d., independently of one another, between approximately 50 mtorr and approximately 500 mtorr for a single-wafer ALD reactor.

8. The method according to claim 1, which further comprises setting the initial pressures in steps b. and d., independently of one another, between approximately 100 mtorr and approximately 300 mtorr for a single-wafer ALD reactor.

9. The method according to claim 1, which further comprises setting the initial pressures in steps b. and d., independently of one another, between approximately 200 mtorr and approximately 800 mtorr for a batch ALD reactor.

10. The method according to claim 1, which further comprises setting the initial pressures in steps b. and d., independently of one another, between approximately 300 mtorr and approximately 700 mtorr for a batch ALD reactor.

11. The method according to claim 1, which further comprises setting the initial pressures in steps b. and d. to be equal.

12. The method according to claim 1, which further comprises setting the pressures built up in steps b. and d. at the end of an introduction of a corresponding precursor to be between approximately 150 mtorr and approximately 1500 mtorr for a single-wafer ALD reactor.

13. The method according to claim 1, which further comprises setting the pressures built up in steps b. and d. at the end of an introduction of a corresponding precursor to be between approximately 400 mtorr and approximately 800 mtorr for a single-wafer ALD reactor.

14. The method according to claim 1, which further comprises setting the pressures built up in steps b. and d. at the end of an introduction of a corresponding precursor to be between approximately 400 mtorr and approximately 600 mtorr for a single-wafer ALD reactor.

15. The method according to claim 1, which further comprises setting the pressures built up in steps b. and d. at the end of an introduction of a corresponding precursor to be between approximately 800 mtorr and approximately 7 torr for a batch ALD reactor.

16. The method according to claim 1, which further comprises setting the pressures built up in steps b. and d. at the end of an introduction of a corresponding precursor to be between approximately 1 torr and approximately 5 torr for a batch ALD reactor.

17. The method according to claim 1, which further comprises repeating steps b. to d. until a desired layer thickness is reached with a pressure after step e. has ended substantially corresponding to the initial pressure for the introduction of the first precursor.

18. The method according to claim 1, which further comprises discharging the first precursor and the second precursor from the reaction chamber through different off-gas lines.

19. The method according to claim 18, which further comprises performing the discharging through the different off-gas lines respectively with dedicated pumps connected to the respective off-gas lines.

20. The method according to claim 18, which further comprises closing off the off-gas lines from the reaction chamber with at least one valve.

21. The method according to claim 18, which further comprises closing off the off-gas lines from the reaction chamber with valves in each of the respective off-gas lines.

22. The method according to claim 1, which further comprises introducing the first and second precursors the reaction chamber through different feedlines.

23. The method according to claim 22, which further comprises providing at least one further feedline for the purge gas.

24. The method according to claim 1, which further comprises providing a dedicated feedline for providing the purge gas.

25. The method according to claim 1, which further comprises selecting the substrate from at least one of the group consisting of a semiconductor substrate, a metal substrate, and an insulating substrate.

26. The method according to claim 1, which further comprises, for an ALD deposition of a ternary system, there are provided the steps of:
f. introducing a third precursor into the reaction chamber such that in the reaction chamber, starting from the initial pressure produced in step e., a pressure rise takes place to effect deposition of a third layer constituent on the substrate surface; and
g. removing the third precursor from the reaction chamber by purging the reaction chamber with a purge gas such that the pressure in the reaction chamber produced in step f. drops.

27. The method according to claim 26, which further comprises, for ALD deposition of a layer system including more than three constituents, step sequences corresponding to steps f. and g. follow for each further precursor.

28. A method for ALD coating of substrates, which comprises:
providing a substrate in a reaction chamber;
starting from an initial pressure, raising the pressure in the reaction chamber by introducing a first precursor therein to effect deposition of a first layer constituent on a surface of the substrate;
purging the reaction chamber with a purge gas to remove the first precursor from the reaction chamber and to reduce the pressure in the reaction chamber substantially back to the initial pressure;
starting from the initial pressure, raising the pressure in the reaction chamber by introducing a second precursor therein to effect deposition of a second layer constituent on the substrate surface; and
purging the reaction chamber with a purge gas to remove the second precursor from the reaction chamber and to drop the pressure in the reaction chamber from the raised pressure caused by introduction of the second precursor.

29. A device for carrying out an ALD process, comprising:
a reaction chamber;
at least one first feedline fluidically connected to said reaction chamber for supplying a first precursor to said reaction chamber;
at least one second feedline fluidically connected to said reaction chamber for supplying a second precursor to said reaction chamber;
at least one purge feedline fluidically connected to said reaction chamber for supplying a purge gas to said reaction chamber;
at least one first off-gas line fluidically connected to said reaction chamber for venting at least some of the first precursor from said reaction chamber; and
at least one second off-gas line fluidically connected to said reaction chamber for venting at least some of the second precursor from said reaction chamber.

30. The device according to claim 29, further comprising:
at least one further feedline fluidically connected to said reaction chamber for supplying at least one further precursor to said reaction chamber; and
at least one further off-gas line fluidically connected to said reaction chamber for venting the at least one further precursor from said reaction chamber.

31. The device according to claim 29, further comprising:
a first pump fluidically connected to said first off-gas line; and
a second pump different from said first pump fluidically connected to said second off-gas line.

32. The device according to claim 30, further comprising a valve fluidically connected to said first and second off-gas lines and closing off said first and second off-gas lines from said reaction chamber.

33. The device according to claim 30, further comprising a valve fluidically connected to said first and second off-gas lines and respectively separately closing off said first and second off-gas lines from said reaction chamber.

34. The device according to claim 30, further comprising two valves each fluidically connected to a respective one of said first and second off-gas lines and respectively selectively opening and closing off said off-gas lines from said reaction chamber.

35. A device for carrying out a deposition process, comprising:
an Atomic Layer Deposition reaction chamber;
at least one first feedline fluidically connected to said reaction chamber for supplying a first precursor to said reaction chamber;
at least one second feedline fluidically connected to said reaction chamber for supplying a second precursor to said reaction chamber;
at least one purge feedline fluidically connected to said reaction chamber for supplying a purge gas to said reaction chamber;
at least one off-gas line fluidically connected to said reaction chamber;
a first valve disposed in said at least one first off-gas line, said first valve venting at least some of the first precursor from said reaction chamber when in an open position;
at least one second off-gas line fluidically connected to said reaction chamber; and
a second valve disposed in said at least one second off-gas line, said second valve venting at least some of the second precursor from said reaction chamber when in an open position.
